(19) United States
(12) Patent Application Publication
(10) Pub. No.: US 2005/0052846 A1
(43) Pub. Date: Mar. 10, 2005

(54) Electronic apparatus having heat dissipation device incorporated therein

(76) Inventors: Chia-jui Lin, Taipei (TW); Kuo-Ching Chang, Taipei (TW); Hsiu-Ming Chang, Taipei (TW); Ke-Nam Wang, Taoyuan (TW)

Correspondence Address: BIRCH STEWART KOLASCH & BIRCH, PO BOX 747, FALLS CHURCH, VA, 22040-0747, US

(21) Appl. No.: 10/932,060

(22) Filed: Sep. 2, 2004

(30) Foreign Application Priority Data
Sep. 5, 2003 (TW) 92124668

(51) Int. Cl. H05K 7/20

(52) U.S. Cl. 361/695

(57) ABSTRACT

An electronic apparatus includes a casing, a light source housed in the casing, and a heat dissipation device positioned between the casing and the light source. The casing is formed with a lead angle on its corner to create an inclined surface. The heat dissipation device has a first and a second end surfaces opposite to each other and a sidewall connected between them. The sidewall of the fan frame neighbors the inclined surface and has a slanting direction substantially paralleled to the inclined surface.

### BACKGROUND OF THE INVENTION

a) Field of the Invention

The present invention relates to an electronic apparatus having a heat dissipation device incorporated therein.

b) Description of Related Art

Referring to FIG. 1, a conventional projector 100 includes a projecting lens 106, a light source 104 placed on the right side of a projecting lens 106, and a fan 102 placed on the right side of the light source 104 for inducing an airflow that exits the projector 100 by an exhaust opening 112 formed on a projector casing 108. A light-shielding mask 112 is placed between the exhaust opening 112 and the fan 102 to avoid the light emitted from the light source 104 escaping out of the projector 100 through the exhaust opening 112.

In a conventional projector, the projector casing 108 is typically formed with a lead angle on its corner to create an inclined surface 108a. In that case, since the fan 102 must be placed at the end of the projector 100 to neighbor the exhaust opening 112, a clearance 110 existing between the fan 102 and the inclined surface 108a becomes considerable. Hence, when air passes through the clearance 110, an irregular flow such as a vortex is created and causes the flow field to be unstable, and thus the heat dissipation efficiency is lowered and a large noise is made.

### SUMMARY OF THE INVENTION

An object of the invention is to provide an electronic apparatus having heat dissipation device with enhanced heat dissipation efficiency incorporated therein.

According to the invention, the electronic apparatus includes a casing, a light source housed in the casing, and a heat dissipation device positioned between the casing and the light source. The casing is formed with a lead angle on its corner to create an inclined surface. The heat dissipation device includes a base, a fan frame mounted on the base, and a fan impeller. The fan frame has a first and a second end surfaces opposite to each other and a sidewall connected between them. The area of the first end surface is larger than that of the second end surface, and the sidewall of the fan frame neighbors the inclined surface and has a slanting direction substantially paralleled to the inclined surface. The fan impeller induces an airflow that enters the heat dissipation device by the first end surface and leaves it by the second end surface.

Through the design of the invention, since the fan frame is adapted to closely neighbor the inclined surface of the projector housing, the heat dissipation device can fully occupy the end space inside the casing to minimize or even eliminate the clearance, so that the irregular flow such as a vortex no longer exists in the flow field. This greatly enhances the heat dissipation efficiency and reduces the noise made by the heat dissipation device.

Also, since the fan frame is designed to have the area of the air inlet larger than that of the air outlet, the air intake performance of the heat dissipation device is increased considerably to further enhance the heat dissipation efficiency.

### BRIEF DESCRIPTION OF THE DRAWINGS

FIG. 1 shows a front view illustrating the arrangement of a heat dissipation device in a conventional projector.

FIG. 2A shows a perspective view illustrating a heat dissipation device according to the invention.

FIG. 2B shows a front view of the heat dissipation device shown in FIG. 2A.

FIG. 2C shows a side view of the heat dissipation device shown in FIG. 2A.

FIG. 3 shows a schematic front view illustrating the arrangement of the heat dissipation device in a projector according to the invention.

FIG. 4A shows another heat dissipation device incorporating a ring structure.

FIG. 4B shows a schematic front view illustrating another arrangement of the heat dissipation device in a projector according to the invention.

### DETAILED DESCRIPTION OF THE INVENTION

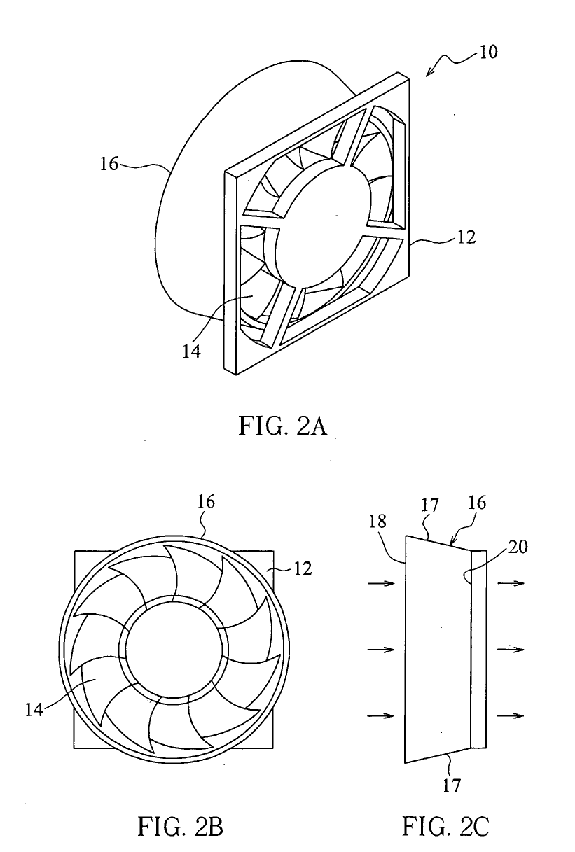

Referring to FIGS. 2A, 2B, and 2C, a heat dissipation device 10 for a projector includes a base 12, a fan impeller 14, and a fan frame 16. The fan frame 16 is mounted on the base 12, and they together define a space to accommodate the fan impeller 14. As shown in FIG. 2C, the fan frame 16 has two end surfaces 18 and 20 opposite to each other and a sidewall 17 connected between them, with one end surface 20 neighboring the base 12 and the other end surface 18 being opposite to the base 12. When the fan impeller 14 rotates, it induces an airflow that enters the heat dissipation device 10 by the end surface 18 and exits by the end surface 20, as indicated by the arrows. In other words, the end surface 18 serves as an air inlet and the end surface 20 serves as an air outlet for the heat dissipation device 10

Referring to FIG. 2C again, the fan frame 16 is designed to have the area of the end surface 18 larger than that of the end surface 20, such that the sidewall 17 of the fan frame 16 slants from the air inlet to the air outlet. According to this embodiment, the fan frame 16 has a shape of a frustum of cone, wherein the end surface 18 is the bottom surface of the frustum of cone and the end surface 20 is the top surface of the same. The invention only requires that the area of the end surface 18 (air inlet) is larger than that of the end surface 20 (air outlet), and the shape of the fan frame 16 is not limited. For example, the surface of the sidewall 17 may be selected from the group consisting of partial sphere, cylindrical surface, conical surface, hyperboloid, paraboloid, ellipsoid, and elliptic cylindrical surface.

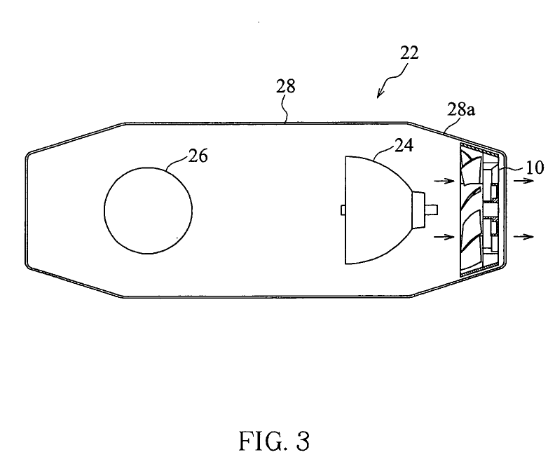

FIG. 3 shows a schematic front view illustrating the arrangement of the heat dissipation device 10 in a projector 22. Referring to FIG. 3, in a projector casing 28 a light source 24 is positioned to the right of a projecting lens 26 and to the left of the heat dissipation device 10. The projector casing 28 is formed with a lead angle on its corner to create an inclined surface 28a, which causes the projector end to converge towards the air outlet.

According to the invention, since the side surface of the fan frame 16 is designed to be slanted, as the fan frame 16 has a slanting direction substantially paralleled to the inclined surface 28a of the projector casing 28, all parts of the fan frame 16 closely neighbor the projector casing 28 to minimize the clearance between the projector casing 28 and the heat dissipation device 10.

Preferably, the fan frame 16 may expand to an extent that allows all its sidewall 17 to touch the inclined surface 28a to eliminate the clearance completely.

Through the design of the invention, since the fan frame 16 is adapted to closely neighbor the inclined surface 28a, the heat dissipation device 10 can fully occupy the end space inside the casing to minimize or even eliminate the clearance, such that the irregular flow such as a vortex no longer exists in the flow field. This enhances the heat dissipation efficiency and reduces the noise made by the heat dissipation device.

Also, since the fan frame 16 is designed to have the area of the end surface 18 (air inlet) larger than that of the end surface 20 (air outlet), the air intake performance of the heat dissipation device is increased considerably to further enhance the heat dissipation efficiency.

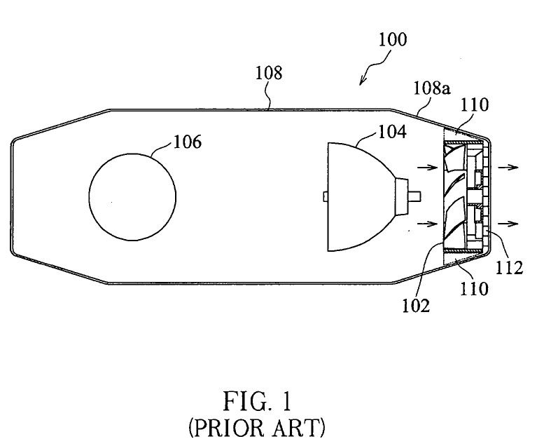

Typically, a light-shielding mask is placed at the exhaust opening of a conventional projector to avoid the light emitted from the light source 24 escaping out of the projector, as in FIG. 1. However, the light-shielding mask may block the flow of air and lower the heat dissipation efficiency as a result.

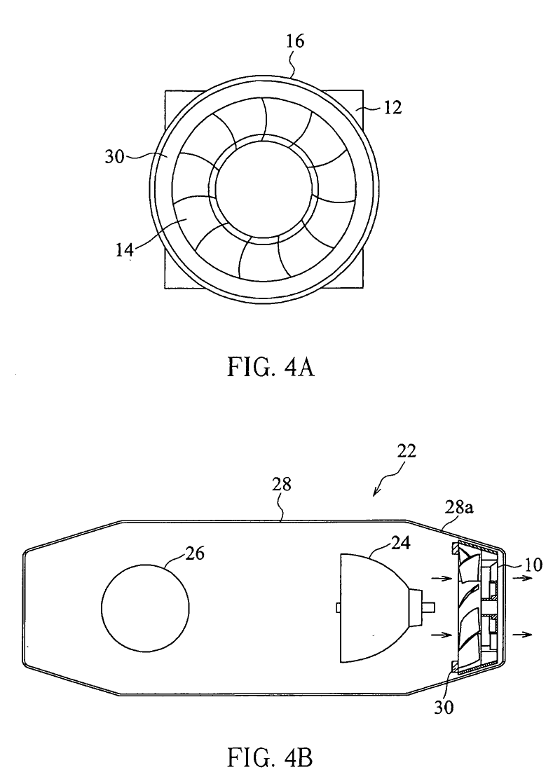

As described above, since the fan frame 16 according to the invention is enlarged towards the air-inlet side, each blade of the fan impeller 14 may further extend outwardly in a radial direction to improve the blade density, and the fan impeller 14 with high blade density may function as a light-shielding mask to block the light emitted from the light source 24. Under the circumstance, when a ring structure 30, with a thickness substantially the same as the interval between the end tip of the blade and the fan frame, is additionally provided in the light path between the light source 24 and the fan impeller 14, as in FIGS. 4A and 4B, the ring structure 30 together with the fan impeller 14 can completely avoid the light escaping out of the projector by the exhaust opening. Thereby, the conventional component of the light-shielding mask can be omitted to further improve the heat dissipation efficiency. Further, referring to FIGS. 4A and 4B, the ring structure 30 may be directly affixed on the periphery of the fan frame on the air-inlet side.

While the invention has been recited by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

1. An electronic apparatus, comprising:
a casing being formed with a lead angle on its corner to create an inclined surface;
a light source housed in the casing; and
a heat dissipation device positioned between the casing and the light source, the heat dissipation device having a first and a second end surfaces opposite to each other and a sidewall connected between them, and the sidewall of the fan frame neighboring the inclined surface and having a slanting direction substantially paralleled to the inclined surface.

2. The electronic apparatus as recited in claim 1, wherein the fan frame has a shape of a frustum of cone.

3. The electronic apparatus as recited in claim 1, wherein the surface of the sidewall is selected from the group consisting of partial sphere, cylindrical surface, conical surface, hyperboloid, paraboloid, ellipsoid, and elliptic cylindrical surface.

4. The electronic apparatus as recited in claim 1, wherein the sidewall touches the casing of the electronic apparatus.

5. The electronic apparatus as recited in claim 1, further comprising a ring structure affixed on the periphery of the fan frame.

6. A heat dissipation device for an electronic apparatus, the casing of the electronic apparatus being formed with a lead angle on its corner to create an inclined surface, the heat dissipation device comprising:
a base;
a fan frame mounted on the base, the fan frame having a first and a second end surfaces opposite to each other and a sidewall connected between them, the area of the first end surface being larger than that of the second end surface, and the sidewall of the fan frame neighboring the inclined surface and having a slanting direction substantially paralleled to the inclined surface; and
a fan impeller housed in the space defined by the base and the fan frame for inducing an airflow that enters the heat dissipation device by the first end surface and exits by the second end surface.

7. The heat dissipation device as recited in claim 6, wherein the fan frame has a shape of a frustum of cone.

8. The heat dissipation device as recited in claim 6, wherein the surface of the sidewall is selected from the group consisting of partial sphere, cylindrical surface, conical surface, hyperboloid, paraboloid, ellipsoid, and elliptic cylindrical surface.

9. The heat dissipation device as recited in claim 6, wherein the sidewall touches the casing of the projector.

10. The heat dissipation device as recited in claim 6, further comprising a ring structure provided in the light path between a light source of the projector and the fan impeller.

11. The heat dissipation device as recited in claim 10, wherein the ring structure is affixed on the periphery of the fan frame.

12. The heat dissipation device as recited in claim 10, wherein the fan impeller has a plurality of blades, and the interval between the end tip of the blade and the sidewall of the fan frame is substantially the same as the thickness of the ring structure.
